(19) United States
(12) Patent Application Publication
(10) Pub. No.: US 2007/0054429 A1
(43) Pub. Date: Mar. 8, 2007

(54) BACK PANEL MANUFACTURING PROCESS

(76) Inventors: Tsuan-Lun Lung, Hsinchu City (TW); Chih-Hung Cheng, Hsinchu County (TW); Yi-Tyng Wu, Chiayi (TW); Shih-Hung Chen, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/161,997

(22) Filed: Aug. 25, 2005

(51) Int. Cl. H01L 51/40; H01L 21/00; H01L 21/44

(52) U.S. Cl. 438/29; 438/99; 438/688

(57) ABSTRACT

A method for manufacturing a back panel on a substrate is provided. The substrate has at least a switching device formed therein and a dielectric layer structure formed thereon. An interconnect structure is also formed in the dielectric layer structure. The method of forming the back panel comprises the step of performing an alloying process. After the alloying process, a pixel mirror layer is formed over the substrate. The pixel mirror layer is electrically connected to the switching device through the interconnect structure. A planar passivation layer is formed on the pixel mirror layer. Then, the planar passivation layer is patterned to expose a portion of the pixel mirror layer.

### BACKGROUND OF THE INVENTION

1. Field of the Invention

The present invention relates to a method of manufacturing the back panel of a display. More particularly, the present invention relates to a method of manufacturing the back panel of a micro display.

2. Description of the Related Art

The display is one of the principle medium for data communication and has become an indispensable part of our daily life. According to the usage, a display can be classified as a large display panel, a family or office television or computer monitor and the display panel of a portable electronic device. Among these categories of applications, portable products have the largest range of designs. Everything from mobile phones, personal digital assistants, electronic books and head-worn displays are real product that uses a miniature display. The main attributes of these products include smallness, lightness, energy efficiency and portability.

The so-called micro display is a finger nail size device. However, together with the proper optical elements, the micro display is display device capable of providing a high level of resolution and displaying considerable information content. The corner-to-corner dimension for these types of display is normally smaller than an inch. Yet, the display can support a display content ranging from QVGA (78 thousand pixels) to UXGA+ (over 2 million pixels), which is a resolution far greater than the resolution of a conventional cathode ray tube (CRT).

At present, the method of manufacturing a micro display, for example, a silicon crystal on silicon (LCOS) micro display or an organic light emitter diode (OLED), includes forming a pixel mirror layer on the upper most layer of an complementary metal-oxide-semiconductor (CMOS) device. The pixel mirror layer is electrically connected to the CMOS device in the substrate so that the CMOS device can serve as a switching device turning the pixel on or off. Thereafter, the pixel mirror layer is patterned to complete the process of manufacturing the back panel of the display. After that, a series of wafer-scale pixel cell processes and die-scale device processes are performed to fabricate a complete micro display.

However, the quality of the pixel mirror layer is directly related to the display quality of the micro display. Therefore, in the manufacturing of back panels, finding a process capable of producing a better pixel mirror layer surface, minimizing the hillock defects on the pixel mirror layer and increasing the reflectivity of the pixel mirror layer is an important technical research topic.

### SUMMARY OF THE INVENTION

Accordingly, at least one objective of the present invention is to provide a method for manufacturing a back panel capable of producing a pixel mirror electrode having fewer hillocks thereon despite the high temperature used in the process of manufacturing the back panel. Hence, the planarity of the pixel mirror layer can be maintained and the yield of the displays can be increased.

At least a second objective of the present invention is to provide a method of manufacturing a pixel unit such that the pixel unit has a planar pixel mirror electrode. Furthermore, the liquid crystal on silicon (LCOS) micro displays or organic light emitter displays (OLED) fabricated using the method of manufacturing pixel unit according to the present invention can have a better display quality.

To achieve these and other advantages and in accordance with the purpose of the invention, as embodied and broadly described herein, the invention provides a method of manufacturing a back panel on a substrate. The substrate has at least a switching device formed therein and a dielectric layer structure formed thereon. An interconnect structure is also formed in the dielectric layer structure. The method of forming the back panel comprises the step of performing an alloying process. After the alloying process, a pixel mirror layer is formed over the substrate. The pixel mirror layer is electrically connected to the switching device through the interconnect structure. A planar passivation layer is formed on the pixel mirror layer. Then, the planar passivation layer is patterned to expose a portion of the pixel mirror layer.

According to the aforementioned back panel manufacturing process in the preferred embodiment of the present invention, the alloying process includes performing a thermal processing operation at a temperature between 350° C. to 450° C.

According to the aforementioned back panel manufacturing process in the preferred embodiment of the present invention, the pixel mirror layer is fabricated using aluminum or titanium.

According to the aforementioned back panel manufacturing process in the preferred embodiment of the present invention, the method of fabricating the planar passivation layer includes forming a passivation layer over the pixel mirror layer and planarizing the passivation layer by performing a chemical-mechanical polishing operation.

According to the aforementioned back panel manufacturing process in the preferred embodiment of the present invention, the switching device includes a complementary metal-oxide-semiconductor (CMOS) device.

In the present invention, because the thermal processing operation (the alloying process) is carried out before forming the pixel mirror layer, the subsequently formed pixel mirror layer will have very little hillocks on the surface as a result of heat. Therefore, the pixel mirror layer not only has a high degree of surface planarity, but the yield of the micro displays can also be increased.

The present invention also provides a method of forming a pixel unit on a substrate. The substrate has at least a switching device formed therein. The method includes performing an alloying process. After the alloying process, a pixel mirror layer is formed over the substrate. The pixel mirror layer is electrically connected to the switching device. Thereafter, a planar passivation layer is formed over the pixel mirror layer. Then, the planar passivation layer is patterned to expose a portion of the pixel mirror layer. After that, a filler material layer and a transparent substrate are formed over the pixel mirror layer. The filler material layer is disposed between the transparent substrate and the exposed pixel mirror layer.

According to the aforementioned method of forming the pixel unit in the preferred embodiment of the present invention, the alloying process includes performing a thermal processing operation at a temperature between 350° C. to 450° C.

According to the aforementioned method of forming the pixel unit in the preferred embodiment of the present invention, the pixel mirror layer is fabricated using aluminum or titanium.

According to the aforementioned method of forming the pixel unit in the preferred embodiment of the present invention, the method of fabricating the planar passivation layer includes forming a passivation layer over the pixel mirror layer and planarizing the passivation layer by performing a chemical-mechanical polishing operation.

According to the aforementioned method of forming the pixel unit in the preferred embodiment of the present invention, the switching device includes a complementary metal-oxide-semiconductor (CMOS) device.

According to the aforementioned method of forming the pixel unit in the preferred embodiment of the present invention, the filler material layer is fabricated from liquid crystal or an organic light emitter material.

According to the aforementioned method of forming the pixel unit in the preferred embodiment of the present invention, the transparent substrate includes a glass panel.

In the present invention, the pixel mirror layer is formed over the substrate after performing a thermal processing operation (an alloying process) of the substrate. This prevents any crystallization on the surface of the pixel mirror layer to form hillocks during the thermal processing operation. Hence, the pixel unit can have a pixel mirror layer with a highly planar surface. Consequently, a liquid crystal on silicon (LCOS) micro display or an organic light emitter display fabricated using the pixel unit fabrication method in the present invention can have a better display quality.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1D are schematic cross-sectional views showing the steps for fabricating the pixel unit of a display according to one preferred embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

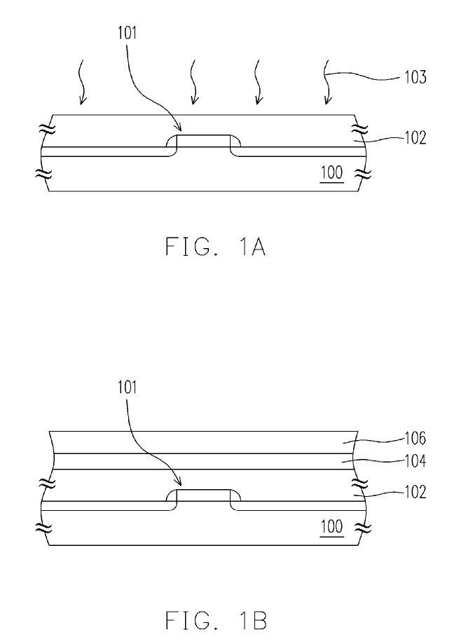

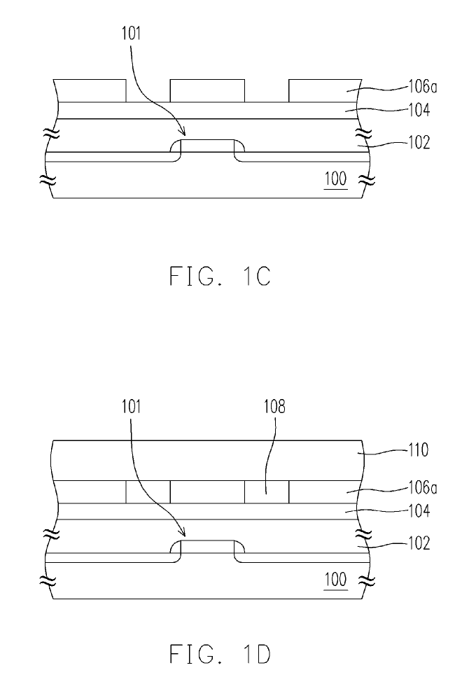

FIGS. 1A through 1D are schematic cross-sectional views showing the steps for fabricating the pixel unit of a display according to one preferred embodiment of the present invention. As shown in FIG. 1A, a substrate 100 is provided. The substrate 100 has at least a switching device 101 formed therein. The switching device 101 can be a complementary metal-oxide-semiconductor (CMOS) device, for example. A dielectric layer structure 102 is also formed over the substrate 100. The dielectric layer structure 102 has an interconnect structure (not shown) formed therein. Thereafter, a thermal processing operation 103 such as an alloying process is carried out. The alloy process is used to improve the metallurgical interaction between the substrate and the interconnect structure. Furthermore, the alloy process can improve the ohmic contact between the devices formed in the substrate and the dielectric layer structure 102. The thermal processing operation 103 is carried out at a temperature between 350° C. to 450° C.

As shown in FIG. 1B, a pixel mirror layer 104 is formed over the substrate 100 after the thermal processing operation 103. The pixel mirror layer 104 is fabricated from a metallic material including aluminum or titanium, for example. The method of forming the pixel mirror layer 104 includes, for example, performing a sputtering process. The pixel mirror layer 104 is electrically connected to switching device 101 in the substrate 100 through the interconnect structure within the dielectric layer structure 102. Thereafter, a passivation layer is formed over the pixel mirror layer 104. The passivation layer 106 is fabricated using silicon nitride or phosphosilicate glass, for example. Then, a planarization process is carried out to planarize the passivation layer 106. The planarization process includes performing a chemical-mechanical polishing operation, for example.

As shown in FIG. 1C, the passivation layer 106 is patterned to form a patterned passivation layer 106a that exposes a portion of the pixel mirror layer 104. Up to this stage, all the steps necessary for forming a back panel have been completed.

As shown in FIG. 1D, a filler material layer 108 and a transparent substrate 110 are formed over the substrate 100 to complete the fabrication of the pixel unit of a display. The filler material layer 108 is disposed between the transparent substrate 110 and the exposed pixel mirror layer 104. According to whether a liquid crystal on silicon (LCOS) micro display or an organic light emitter display (OLED) is produced, the filler material layer 108 is liquid crystal, organic light emitter material or high molecular weight light-emitting material, for example. The transparent substrate 100 is a panel made from glass, indium-tin-oxide compound or indium-zinc-oxide compound, for example.

In summary, the pixel mirror layer is formed over the substrate after performing a thermal processing operation (an alloying process) of the substrate in the present invention. This prevents any crystallization on the surface of the pixel mirror layer to form hillocks during the thermal processing operation. Hence, the pixel unit can have a pixel mirror layer with a highly planar surface. Consequently, a liquid crystal on silicon (LCOS) micro display or an organic light emitter display fabricated using the pixel unit fabrication method in the present invention can have a better display quality. In other words, no high temperature thermal processing operation (alloying operation) is carried out after forming the pixel mirror layer so that hillocks will not be formed on the surface of the pixel mirror layer due to heat. As a result, a high degree of planarity in the pixel mirror layer can be maintained and the yield of the displays can be increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A process of manufacturing back panel on a substrate having at least a switching device formed therein and a dielectric layer structure thereon, wherein the dielectric layer structure has an interconnect structure formed therein, the back panel manufacturing process comprising the steps of:
performing an alloying process; forming a pixel mirror layer over the substrate after the alloying process, wherein the pixel mirror layer is electrically connected to the switching device through the interconnect structure;
forming a planar passivation layer over the pixel mirror layer; and
patterning the planar passivation layer to expose a portion of the pixel mirror layer.

2. The back panel manufacturing process of claim 1, wherein the alloying process includes performing a thermal processing operation at a temperature between about 350° C. to 400° C.

3. The back panel manufacturing process of claim 1, wherein the material used for forming the pixel mirror layer is selected from a group consisting of aluminum and titanium.

4. The back panel manufacturing process of claim 1, wherein the step of forming the planar passivation layer includes:
forming a passivation layer over the pixel mirror layer; and
planarizing the passivation layer by performing a chemical-mechanical polishing operation.

5. The back panel manufacturing process of claim 1, wherein the switching device includes a complementary metal-oxide-semiconductor (CMOS) device.

6. A method for forming a pixel unit on a substrate having at least a switching device formed therein, comprising the steps of:
performing an alloying process;
forming a pixel mirror layer over the substrate after performing the alloying process,
wherein the pixel mirror layer connects electrically with the switching device;
forming a planar passivation layer over the pixel mirror layer;
patterning the planar passivation layer to expose a portion of the pixel mirror layer; and
forming a filler material layer and a transparent substrate over the exposed pixel mirror layer, wherein the filer material layer is disposed between the transparent substrate and the pixel mirror layer.

7. The method of forming a pixel unit of claim 6, wherein the alloying process includes performing a thermal processing operation at a temperature between about 350° C. to 400° C.

8. The method of forming a pixel unit of claim 6, wherein the material used for forming the pixel mirror layer is selected from a group consisting of aluminum and titanium.

9. The method of forming a pixel unit of claim 6, wherein the step of forming the planar passivation layer includes:
forming a passivation layer over the pixel mirror layer; and
planarizing the passivation layer by performing a chemical-mechanical polishing operation.

10. The method of forming a pixel unit of claim 6, wherein the switching device includes a complementary metal-oxide-semiconductor (CMOS) device.

11. The method of forming a pixel unit of claim 6, wherein the material used for forming the filler material layer includes liquid crystal or organic light emitter material.

12. The method of forming a pixel unit of claim 6, wherein the transparent substrate includes a glass panel.
